(19) United States
(12) Patent Application Publication
(10) Pub. No.: US 2008/0168161 A1
(43) Pub. Date: Jul. 10, 2008

(54) SYSTEMS AND METHODS FOR MANAGING FAULTS WITHIN A HIGH SPEED NETWORK EMPLOYING WIDE PORTS

(75) Inventors: Gregg S. Lucas, Tucson, AZ (US); Thomas S. Truman, Tucson, AZ (US)

Correspondence Address: CANTOR COLBURN LLP - IBM TUSCON DIVISION, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/621,691

(22) Filed: Jan. 10, 2007

(51) Int. Cl. G01R 31/08; G06F 15/173

(52) U.S. Cl. 709/223; 370/217

(57) ABSTRACT

Systems and methods for managing faults within a high speed network employing wide ports. Exemplary embodiments include a system including a switch module coupled to an end device, the switch device and the end device each have a plurality of PHYs, each of the PHYs on the switch module coupled to a corresponding PHY on the end device, a plurality of wide port cables connected between the switch module and the end device, wherein the coupling of the switch module and the end device defines a wide port, and a process residing on the wide port, the process configured to diagnose faults on the PHYs and having instructions to identify an operational PHY, instruct the operational PHY to take command over the remaining PHYs in the wide port, execute diagnostic sub-routines within the port to identify failed PHYs and report diagnostic data to the operational PHY.

### BACKGROUND OF THE INVENTION

1. Field of the Invention

This invention relates to storage networks, and particularly to systems and methods for managing faults within a high speed network employing wide ports.

2. Description of Background

In storage network systems, high speed serial differential signaling is used to provide high bandwidth connections between a central SAS (serial attached SCSI) switch and other endpoints such as other switches or downstream or upstream storage components. SAS configurations can grow to include myriad SAS ports in order to achieve required connectivity for performance and availability. Configurations typically used fiber channel, Ethernet, SCSI, etc. SAS can implement various topologies, for example, a SAS Switch may have 16 external SAS ports and the SAS ports may be configured, in the field, to be “wide” ports or narrow ports. A wide port includes multiple single links (PHYs). For example, four single links may be combined to form a single 4× wide port. Other configurations are possible. Such various connectivity configurations are accomplished using cables, which introduce another possible point of failure in the storage network. As such it is necessary to be able to identify and isolate cable faults to the specific cable and to not implicate componentry (e.g. logic/adapter cards) as being associated with the cable failures.

Current fiber channel based storage systems are constrained to using a single PHY (i.e. Fiber Channel port) for testing and isolating faults over the same interface that is suspect of being faulty. FIG. 1 illustrates a system 100 with one master switch 110 servicing multiple downstream disk enclosures 120, each interface between the master switch 110 and the enclosure 120 being a single PHY wide. FIG. 2 illustrates a system 200 having multiple masters 210 servicing multiple disk enclosures 220, thereby implementing different methods of wrapping the interfaces for fault detection and isolation. Master/enclosure A illustrates a normal data transfer example. Master/enclosure B illustrates an example of diagnostics implementing internal loopback at each end. Master/enclosure C illustrates an example of a diagnostic loopback at the end device. If multiple ports were to be used in testing a single Fiber Channel interface, those ports would become unavailable during normal run time operations.

For SAS Storage Systems that employ wide ports for attaching storage, the current art is similar to how Fiber Channel interfaces are tested, that is, diagnostic routines are invoked from the (SAS) Switch to the PHYs under test within the wide port (FIG. 2 also applies). The port is treated as a single logical interface. If a failure is detected the port is deemed faulty.

### SUMMARY OF THE INVENTION

Exemplary embodiments include a system for managing faults within a high speed network employing wide ports, the system including a switch module coupled to an end device, the switch device and the end device each have a plurality of PHYs, each of the PHYs on the switch module coupled to a corresponding PHY on the end device, a plurality of wide port cables connected between the switch module and the end device, wherein the coupling of the switch module and the end device defines a wide port, and a process residing on the wide port, the process configured to diagnose faults on the PHYs and having instructions to identify an operational PHY, instruct the operational PHY to take command over the remaining PHYs in the wide port, execute diagnostic sub-routines within the port to identify failed PHYs and report diagnostic data to the operational PHY.

Additional embodiments include a method for managing faults within a high speed network employing wide ports, the method including configuring a wide port on the high speed network, determining whether to run a diagnostic process within the wide port, in response to determining to run the diagnostic process, defining a command PHY within the wide port, running the diagnostic process, identifying a failed PHY on the wide port and reporting failed PHY information to an initiator on the wide port.

Further embodiments include a computer readable medium having computer executable instructions for performing a method for managing faults within a high speed network employing wide ports, the method including configuring a wide port on the high speed network, determining whether to run a diagnostic process within the wide port, in response to determining to run the diagnostic process, defining a command PHY within the wide port, running the diagnostic process, identifying a failed PHY on the wide port and reporting failed PHY information to an initiator on the wide port.

System and computer program products corresponding to the above-summarized methods are also described and claimed herein.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### TECHNICAL EFFECTS

As a result of the summarized invention, technically systems and methods for managing faults within a high speed network employing wide ports have been achieved.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 illustrates a prior art system with one master switch servicing multiple downstream disk enclosures;

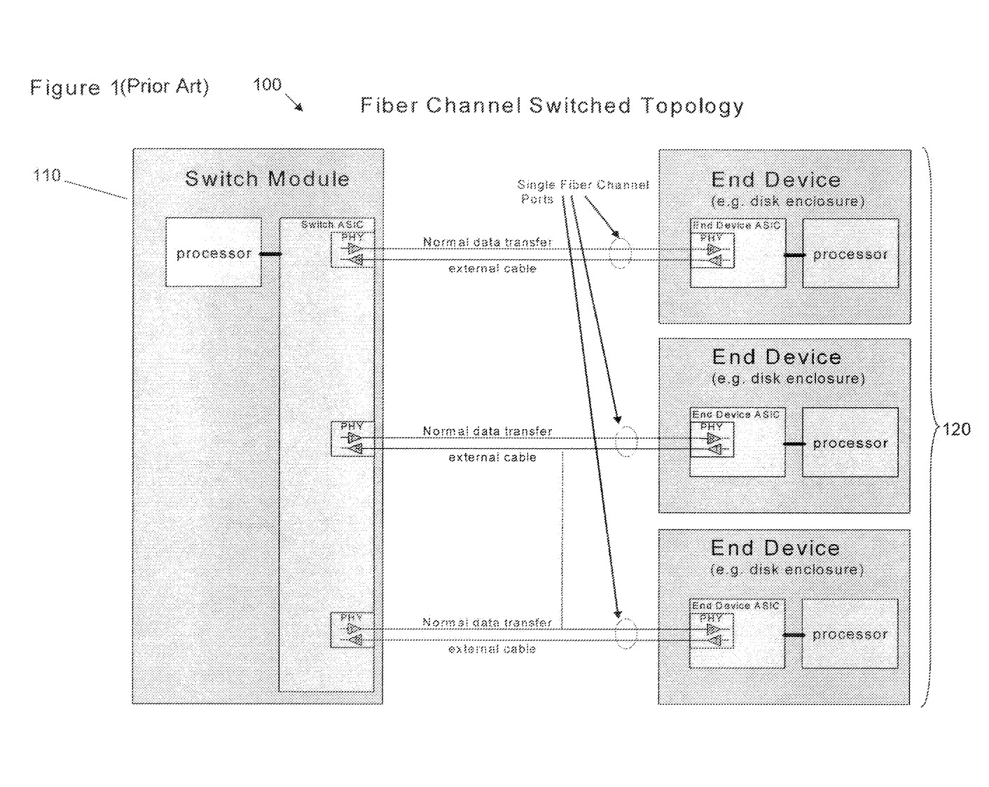

FIG. 2 illustrates a prior art system having multiple masters servicing multiple disk enclosures 220;

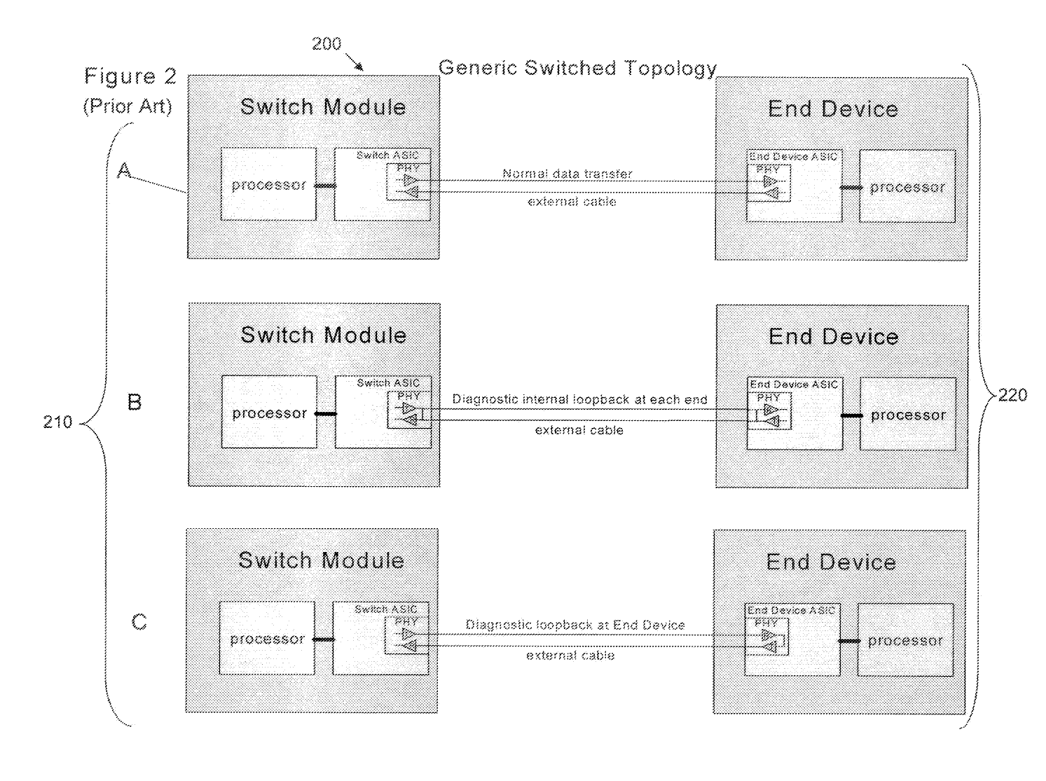

FIG. 3 illustrates an exemplary embodiment of a SAS storage system for managing faults within a high speed network employing wide ports; and

FIG. 4 illustrates a method 400 for managing faults within a high speed network employing wide ports.

The detailed description explains the preferred embodiments of the invention, together with advantages and features, by way of example with reference to the drawings.

### DETAILED DESCRIPTION OF THE INVENTION

Exemplary embodiments include SAS storage systems that are generally architected to use wide SAS Ports. In exemplary implementations, a wide port includes more than one SAS PHYs (links) combined as a single logical port with all PHYs using a common SAS address. To detect and isolate faults within the SAS port, which includes the initiator (SAS Switch) and end devices, a method and procedure is employed which utilizes the PHYs as independent resources during special diagnostic modes. One resource establishes communication between the switch and end devices whereby, it executes and supervises diagnostic routines. Running such routines, the remaining resources are independently tested to determine if any faults exist within the wide port.

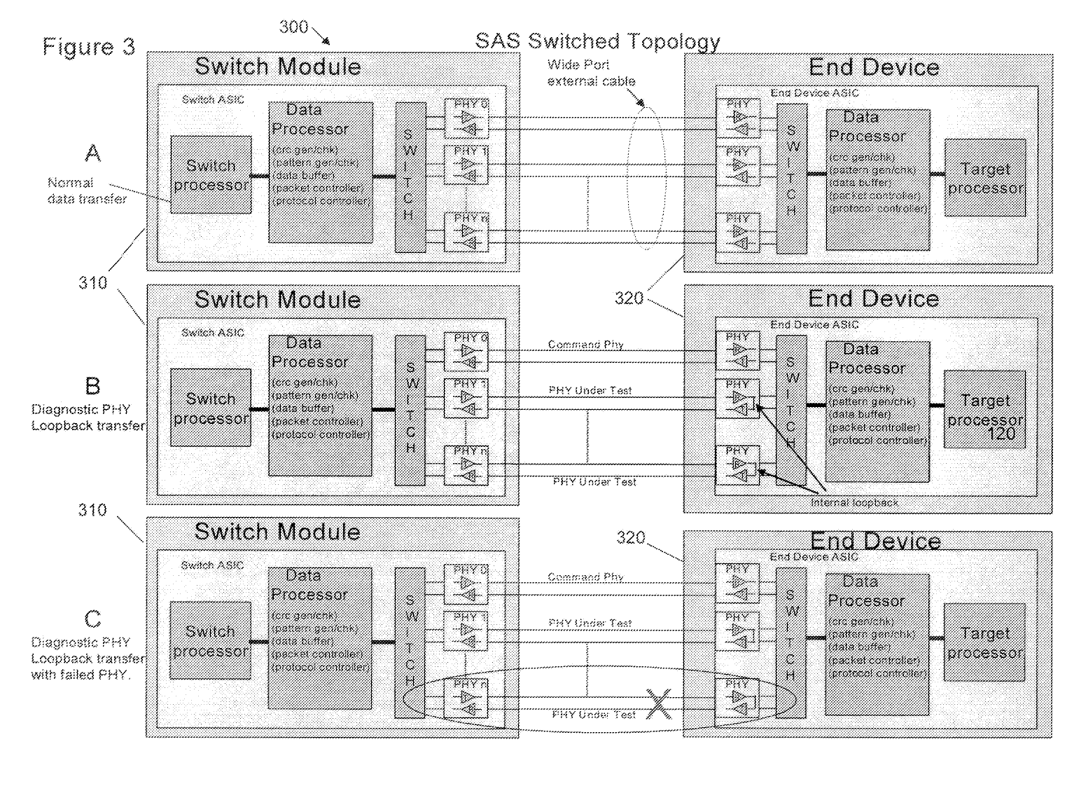

FIG. 3 illustrates an exemplary embodiment of a SAS storage system 300 for managing faults within a high speed network employing wide ports. System 300 illustrates several switch modules 310 coupled to end devices 320. Switch devices 310 each include a switch processor, data processor, switch and multiple PHYs. Similarly, end devices 320 each include a target processor, data processor, switch and multiple PHYs. Switch Module/End device A illustrates an example of a system using a wide port external cable during normal data transfer. Switch Module/End device B illustrates an example of a system using a wide port external cable during a diagnostic PHY loopback transfer. Switch Module/End device C illustrates an example of a system using a wide port external cable during a diagnostic PHY loopback transfer with a failed PHY. The failed PHY can easily be reported by the operational Command PHY.

SAS storage systems are generally architected to use wide SAS ports. These configurations are unique topologies that are brought about by virtue of the new architecture being defined in the SAS T10 standard committee today. Therefore, such a flexible storage topology has not been available. This flexibility affords new opportunities such as described herein.

SAS wide ports include multiple single PHYs or links. A link is likened to a port in today's fiber channel systems. Generally, a SAS Wide port is defined and used as a single logical port, using multiple PHYs to achieve improved performance and availability characteristics. SAS I/O transactions that target a wide port, transfer data on all the PHYs within the port. For example, if 4 KB of data is to be transferred over a wide port that consists of 4 PHYs, 1 KB of data could be allocated to each of the single PHYs within that port and all 4 KB would be concurrently transferred. If one PHY fails, its traffic is routed to the remaining good PHYs within that port. Exemplary embodiments utilize such multi PHY capability. In general, as part of the diagnostic process, it is unknown which PHYs are good or bad so data traffic is routed to all PHYs. If a PHY is good it reports good status, if the PHY is bad it may or may not be able to report status, at worst, the failed PHY interface times out and the command PHY detects it as such.

In SAS storage systems employing wide ports, during normal data transfer scenarios, when a fault is detected (or when a system is initially powered on), diagnostic test routines are required to test the failed SAS port(s). To detect and isolate faults within a SAS wide port, which includes the initiator (SAS switch) and end devices, a method and procedure is employed which utilizes the PHYs as independent resources. Within the wide port a routine is invoked to identify which PHY(s) has failed. It is expected that at least one PHY is operational. The first operational PHY that is established assumes Command over the remaining PHYs within the port. This command PHY further executes diagnostic subroutines to each of the remaining PHYs within the port. These subroutines independently test each remaining PHYs for “pass” or “fail” status. Subsequently, the Command PHY identifies the failed interface and reports diagnostic information to the initiator for further isolation. In general, an initial PHY is chosen to become the Command PHY. A simple algorithm can be employed that starts with PHY 0 of the wide port and ratchets thru all the PHYs until an operational PHY is determined. For example, the first PHY that is tried or the last PHY that is tried may be the operation PHY. It is possible that no PHYs are good, which can subsequently be reported.

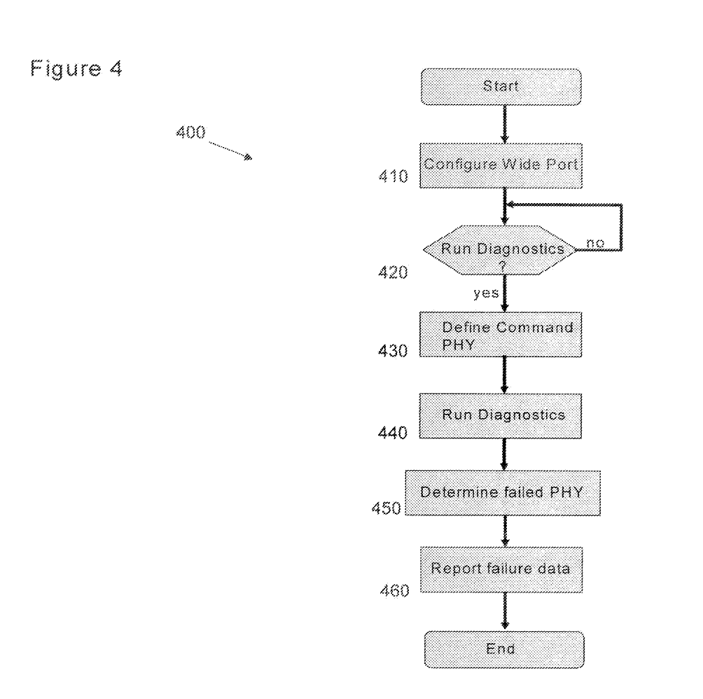

FIG. 4 illustrates a method 400 for managing faults within a high speed network employing wide ports. At step 410, the wide ports are configured. At step 420 it is determined whether or not the diagnostics are to be run. If the diagnostics are run, then at step 430, command PHYs are defined as discussed above. At step 440, diagnostics are then run. At step 450, the failed PHY or multiple failed PHYs are determined. Then at step 460, the failure data is reported.

In the above-described embodiments, the use of a cable as a communication medium has been discussed. It is appreciated that in other embodiments, hardwired solutions can be implemented. For example, in IBM's BladeCenter wide ports are distributed between server blades and SAS Switch Modules and the interconnect medium is a midplane board with embedded signal traces. The midplane approach is often referred to as a high speed fabric.

The capabilities of the present invention can be implemented in software, firmware, hardware or some combination thereof.

As one example, one or more aspects of the present invention can be included in an article of manufacture (e.g., one or more computer program products) having, for instance, computer usable media. The media has embodied therein, for instance, computer readable program code means for providing and facilitating the capabilities of the present invention. The article of manufacture can be included as a part of a computer system or sold separately.

Additionally, at least one program storage device readable by a machine, tangibly embodying at least one program of instructions executable by the machine to perform the capabilities of the present invention can be provided.

The flow diagrams depicted herein are just examples. There may be many variations to these diagrams or the steps (or operations) described therein without departing from the spirit of the invention. For instance, the steps may be performed in a differing order, or steps may be added, deleted or modified. All of these variations are considered a part of the claimed invention.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A system for managing faults within a high speed network employing wide ports, the system comprising:
a switch module coupled to an end device, the switch device and the end device each have a plurality of PHYs, each of the PHYs on the switch module coupled to a corresponding PHY on the end device;
a plurality of wide port cables connected between the switch module and the end device, wherein the coupling of the switch module and the end device defines a wide port; and
a process residing on the wide port, the process configured to diagnose faults on the PHYs and having instructions to:
identify an operational PHY;
instruct the operational PHY to take command over the remaining PHYs in the wide port;
execute diagnostic sub-routines within the port to identify failed PHYs; and
report diagnostic data to the operational PHY.

2. The system as claimed in claim 1 wherein the switch module and the end device each comprise:
a data processor; and
a switch coupled to the data processor and the plurality of PHYs.

3. The system as claimed in claim 2 wherein each data processor further comprises a data buffer, a packet controlled and a protocol controller.

4. The system as claimed in claim 3 wherein the switch module further comprises a switch processor coupled to the data processor residing on the switch module.

5. The system as claimed in claim 4 wherein the end device further comprises a target processor coupled to the data processor residing on the end device.

6. The system as claimed in claim 5 wherein the process is configured to generate a diagnostic PHY loopback transfer on the wide port.

7. The system as claimed in claim 6 wherein the process is configured to route data traffic over remaining good PHYs within the wide port.

8. The system as claimed in claim 7 wherein the switch residing on the switch module is an initiator to which failed PHY information is transferred by the process.

9. A method for managing faults within a high speed network employing wide ports, the method comprising:
configuring a wide port on the high speed network;
determining whether to run a diagnostic process within the wide port;
in response to determining to run the diagnostic process, defining a command PHY within the wide port;
running the diagnostic process;
identifying a failed PHY on the wide port; and
reporting failed PHY information to an initiator on the wide port.

10. The method as claimed in claim 9, wherein the high speed network comprises:
a switch module coupled to an end device, the switch module and the end device each have a plurality of PHYs, each of the PHYs on the switch module coupled to a corresponding PHY on the end device; and
a plurality of wide port cables connected between the switch module and the end device, wherein the coupling of the switch module and the end device defines the wide port.

11. The method as claimed in claim 10 wherein the diagnostic comprises instructions to:
instruct the command PHY to take command over the remaining PHYs in the wide port;
execute diagnostic sub-routines within the port to identify failed PHYs; and
report diagnostic data to the initiator.

12. The method as claimed in claim 11 wherein the diagnostic process is configured to generate a diagnostic PHY loopback transfer on the wide port.

13. The method as claimed in claim 12 wherein the diagnostic process is configured to:
route data traffic to all PHYs
determine if individual PHYs are good and to report a good status;
determine if individual PHYs are bad and to report a bad status if the bad PHY is able to report its status; and
to detect a PHY interface timeout if all PHYs are bad and unable to report status.

14. The method as claimed in claim 13 wherein the switch module comprises:
a switch processor; and
a data processor coupled to the switch processor,
wherein the data processor is coupled to the initiator and to the PHYs residing on the switch module, the initiator receiving the diagnostic data from the wide port as generated by the diagnostic process.

15. The method as claimed in claim 14 wherein the diagnostic data includes the failed PHY information.

16. A computer readable medium having computer executable instructions for performing a method for managing faults within a high speed network employing wide ports, the method comprising:
configuring a wide port on the high speed network;
determining whether to run a diagnostic process within the wide port;
in response to determining to run the diagnostic process, defining a command PHY within the wide port;
running the diagnostic process;
identifying a failed PHY on the wide port; and
reporting failed PHY information to an initiator on the wide port.

17. The computer readable medium as claimed in claim 16 wherein the method further comprises:
instructing the command PHY to take command over the remaining PHYs in the wide port;
executing diagnostic sub-routines within the port to identify failed PHYs; and
reporting diagnostic data to the initiator.

18. The computer readable medium as claimed in claim 16 wherein the diagnostic data includes the failed PHY information.

19. The computer readable medium as claimed in claim 16 wherein the method further comprises generating a diagnostic PHY loopback transfer on the wide port.

20. The computer readable medium as claimed in claim 16 wherein the method further comprises routing data traffic over remaining good PHYs within the wide port.
